(19) United States
(12) Patent Application Publication
(10) Pub. No.: US 2019/0221953 A1
(43) Pub. Date: Jul. 18, 2019

(54) ELECTRICAL CONNECTOR

(71) Applicant: LOTES CO., LTD, Keelung (TW)

(72) Inventors: Zhi Lin Chen, Keelung (TW); Xiang Fang Lei, Keelung (TW)

(21) Appl. No.: 16/242,309

(22) Filed: Jan. 8, 2019

(30) Foreign Application Priority Data
Jan. 17, 2018 (CN) 201810045877.0

(51) Int. Cl. H01R 12/71; H01R 12/55; H01R 12/70; H01R 13/502; H01R 13/516; H01R 13/73; H05K 1/11

(52) U.S. Cl. CPC H01R 12/716; H01R 12/55; H01R 12/7082; H05K 1/11; H01R 13/516; H01R 13/73; H01R 13/502

(57) ABSTRACT

An electrical connector is used to be electrically connected to a circuit board. The circuit board has a sink plate groove, and the electrical connector is mounted in the sink plate groove. The sink plate groove has at least one groove wall, and the groove wall has at least one first contact area. The electrical connector includes: an insulating body; a plurality of terminals, accommodated in the insulating body; an inner shell, accommodated in the insulating body; and an outer shell, provided outside the inner shell and electrically connected with the first contact area.

### CROSS-REFERENCE TO RELATED PATENT APPLICATION

This non-provisional application claims priority to and the benefit of, pursuant to 35 U.S.C. § 119(a), patent application Serial No. CN201810045877.0 filed in China on Jan. 17, 2018. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present invention relates to an electrical connector, and particularly to a sink plate type electrical connector.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The existing commercial sink plate type electrical connector generally includes an insulating body, a plurality of terminals retained on the insulating body, and a shielding shell that accommodates the insulating body. The shielding shell has a plurality of circuit board mounting pins. The electrical connector is mounted to mounting holes in the circuit board via the mounting pins, and the mounting pins are soldered with the mounting holes. The circuit board has a sink plate groove, and the electrical connector is located in the sink plate groove.

The method of fixing the electrical connector to the circuit board is simple. However, in practical use, when a user holds a mating connector and inserts it into the electrical connector, the electrical connector may be shaken up and down. If the electrical connector is inserted frequently, the mounting pins may be shaken out from the mounting holes, such that the electrical connector is separated from the circuit board and cannot work.

Therefore, a heretofore unaddressed need to design an improved electrical connector exists in the art to address the aforementioned deficiencies and inadequacies.

### SUMMARY

In view of the above deficiencies in the background, the present invention is directed to an electrical connector. A shell of the electrical connector is soldered with a groove wall of a sink plate groove of a circuit board, such that the electrical connector is fixed on the circuit board more stably.

To achieve the foregoing objective, the present invention adopts the following technical solutions:

An electrical connector is configured to be electrically connected to a circuit board. The circuit board has a sink plate groove, the electrical connector is mounted in the sink plate groove, the sink plate groove has at least one groove wall, and the groove wall has at least one first contact area. The electrical connector includes: an insulating body; a plurality of terminals, accommodated in the insulating body; an inner shell, accommodated in the insulating body; and an outer shell, provided outside the inner shell, and configured to be electrically connected with the at least one first contact area.

In certain embodiments, the outer shell has a top wall and two side walls connected with the top wall, and outer surfaces of the side walls are configured to be electrically connected with the at least one first contact area.

In certain embodiments, a bottom wall is opposite to the top wall, the side walls are connected with the top wall and the bottom wall, and the top wall, the side walls and the bottom wall are surroundingly provided outside the inner shell.

In certain embodiments, each of the side walls has a vertical abutting surface, and the vertical abutting surface is configured to be electrically connected with the first contact area.

In certain embodiments, an area of the first contact area is greater than an area of the vertical abutting surface.

In certain embodiments, the groove wall is concavely provided with a groove, the first contact area is located in the groove and exposed from the sink plate groove, and a surface of the first contact area does not exceed a surface of the groove wall.

In certain embodiments, the circuit board is provided with a plurality of second contact areas, the second contact areas are respectively located on a left side, a right side and a rear side of the sink plate groove, a plurality of mounting pins extend from two sides of the outer shell, at least one of the mounting pins extends from each of the two sides of the outer shell, and the mounting pins are configured to be electrically connected with the second contact areas.

In certain embodiments, each of the mounting pins comprises at least one first mounting portion and at least one second mounting portion, the first mounting portions of the mounting pins respectively extend from two sides of a front end of the outer shell, the second mounting portions of the mounting pins respectively extend from two sides of a tail end of the outer shell, the first mounting portions of the mounting pins are configured to be respectively electrically connected with the second contact areas on the left and right sides of the sink plate groove, the second mounting portions of the mounting pins are configured to be respectively electrically connected with the second contact areas on the rear side of the sink plate groove, and the first contact area is located between the first mounting portions and the second mounting portions of the mounting pins.

In certain embodiments, the insulating body is provided with a base and a tongue extending forward from the base, the terminals are retained on the base in an upper row and a lower row and are partially exposed from an upper surface and a lower surface of the tongue, a middle shielding plate is accommodated in the base and the tongue and located between the upper and lower rows of terminals, and the inner shell is surroundingly provided outside the tongue to form an insertion space therebetween.

In certain embodiments, the inner shell has at least one elastic sheet extending to the insertion space, and the outer shell is provided with a reserved hole corresponding to the elastic sheet.

In certain embodiments, a first abutting portion extends upward from each of two sides of a tail end of the inner shell, a second abutting portion extends downward from each of the two sides of a tail end of the outer shell, and the first abutting portion abuts the second abutting portion.

In certain embodiments, the first abutting portion is in plate surface contact with the second abutting portion.

Further provided is another technical solution: an electrical connector is configured to be electrically connected to a circuit board. The circuit board has a sink plate groove, the electrical connector is mounted in the sink plate groove, the sink plate groove has at least one groove wall, and the groove wall has at least one first contact area. The electrical connector includes: an insulating body; a plurality of terminals, respectively accommodated in the insulating body; and a shielding shell, accommodated in the insulating body and configured to be electrically connected with the first contact area, wherein at least two mounting pins respectively extend from two sides of the shielding shell and configured to be electrically connected with the second contact areas.

In certain embodiments, the shielding shell comprises an inner shell and an outer shell, the inner shell is accommodated in the insulating body, and the outer shell is provided outside the inner shell and configured to be electrically connected with the first contact area.

In certain embodiments, the outer shell has a top wall, a bottom wall opposite to the top wall and two side walls connected with the top wall and the bottom wall, and outer surfaces of the side walls are configured to be electrically connected with the first contact area.

In certain embodiments, each of a left side and a right side of the sink plate groove has one of the second contact areas, a rear side of the sink plate groove has two of the second contact areas, the at least two mounting pins comprise two first mounting portions, the two first mounting portions respectively extend from two sides of a front end of the outer shell and are configured to be respectively electrically connected with the second contact areas on the left side and the right side of the sink plate groove, and each of the first mounting portions has a first supporting portion configured to abut the circuit board.

In certain embodiments, the at least two mounting pins further comprise two second mounting portions, the two second mounting portions respectively extend from two sides of a tail end of the outer shell and are configured to be respectively electrically connected with the second contact areas on the rear side of the sink plate groove, and the first contact area is located between the first mounting portions and the second mounting portions.

In certain embodiments, the circuit board has a plurality of mounting holes, the second contact areas are provided on the mounting holes, and the first mounting portions and the second mounting portions are mounted in the mounting holes and configured to be fixed with the mounting holes by soldering.

In certain embodiments, a first abutting portion extends upward from each of two sides of the inner shell, a second abutting portion extends downward from each of the two sides of the outer shell, the second abutting portion is located between the first mounting portions and the second mounting portions, a first abutting portion extends upward from each of two sides of the inner shell, and the first abutting portion abuts the second abutting portion.

In certain embodiments, the side walls comprise a front wall and a rear wall, the rear wall is configured to be electrically connected with the first contact area and is located between the first mounting portions and the second mounting portions, the rear wall has a vertical abutting surface, and an area of the first contact area is greater than an area of the vertical abutting surface.

Compared with the related art, certain embodiments of the present invention have the following beneficial effects:

The groove wall of the circuit board is provided with the first contact area, and the outer shell is electrically connected with the first contact area. Thus, compared with the existing electrical connector which is fixed with the circuit board via mounting pins only, the electrical connector of the present invention is fixed with the circuit board more stably, will not be separated from the circuit board due to multiple times of insertion shaking, and is ensured to work stably.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a perspective assembled view of an electrical connector and a circuit board according to certain embodiments of the present invention;

FIG. 2 is a perspective exploded view of the electrical connector and the circuit board according to certain embodiments of the present invention;

FIG. 3 is a perspective assembled view from another perspective of the electrical connector according to certain embodiments of the present invention;

FIG. 4 is a top view of the electrical connector and the circuit board according to certain embodiments of the present invention;

FIG. 5 is a soldering assembled view of the electrical connector and the circuit board according to certain embodiments of the present invention;

FIG. 6 is a bottom view of the electrical connector and the circuit board according to certain embodiments of the present invention; and

FIG. 7 is a sectional view of a combination of the electrical connector and the circuit board according to certain embodiments of the present invention.

### DETAILED DESCRIPTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the terms “comprising”, “including”, “carrying”, “having”, “containing”, “involving”, and the like are to be understood to be open-ended, i.e., to mean including but not limited to.

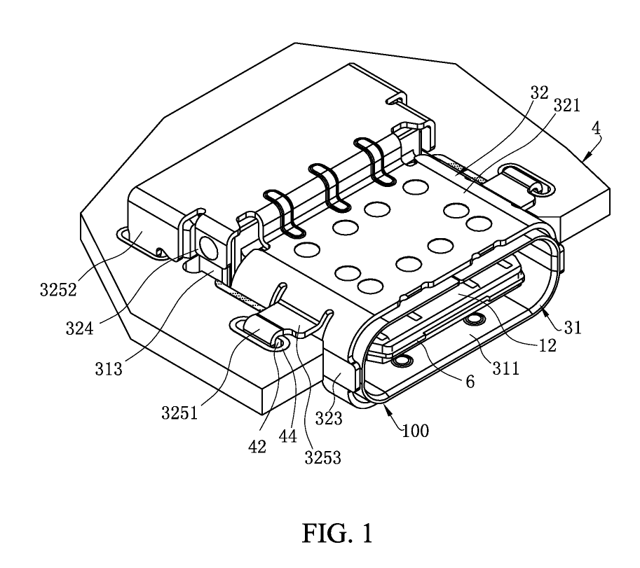

The description will be made as to the embodiments of the present invention in conjunction with the accompanying drawings in FIGS. 1-7. In accordance with the purposes of this invention, as embodied and broadly described herein, this invention, in one aspect, relates to an electrical connector.

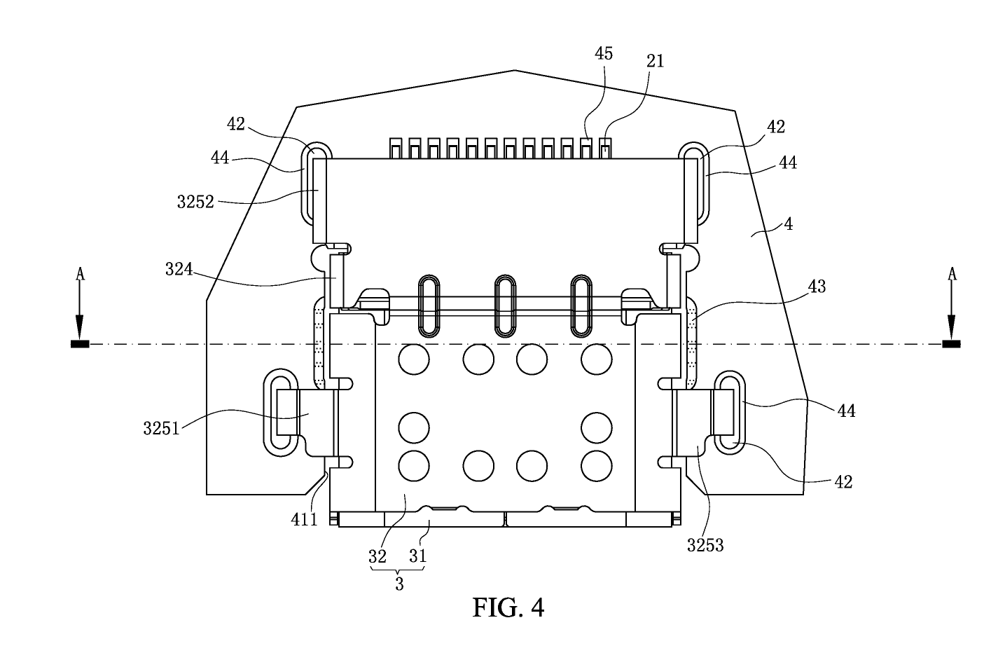

As shown in FIG. 1 and FIG. 4, an electrical connector 100 according to certain embodiments of the present invention, which is electrically connected to a circuit board 4, includes an insulating body 1, a plurality of terminals 2 accommodated in the insulating body 1 and a shielding shell 3 accommodated in the insulating body 1.

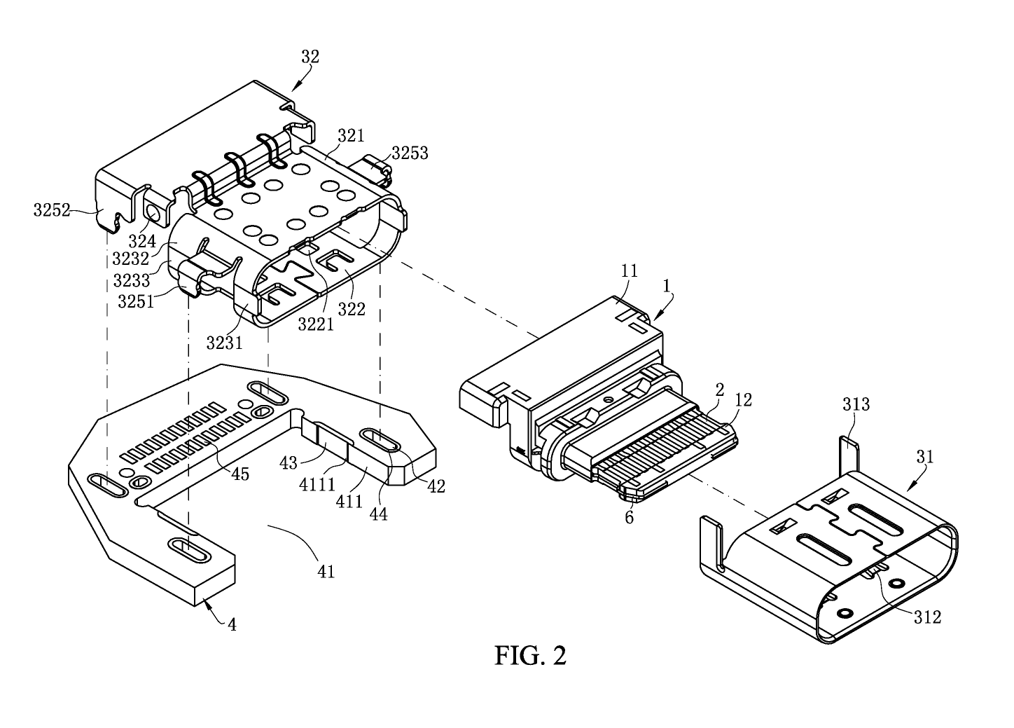

As shown in FIG. 1 and FIG. 2, the circuit board 4 has a sink plate groove 41, and the electrical connector 100 is mounted in the sink plate groove 41. The sink plate groove 41 has at least one groove wall 411, and the groove wall 411 has a groove 4111. At least one first contact area 43 is provided in the groove 4111, and the first contact area 43 is exposed to the sink plate groove 41 and does not exceed the surface of the groove wall 411, so as to prevent the first contact area 43 from interfering with the shielding shell 3. A second contact area 44 is provided on each of the left and right sides of the sink plate groove 41. Two first contact areas 43 are provided on the rear side of the sink plate groove 41, and a plurality of third contact areas 45 is located on the rear side of the sink plate groove 41. In this embodiment, a plurality of mounting holes 42 is provided at the two sides and the rear side of the sink plate groove 41, and the second contact areas 44 are located in the mounting holes 42.

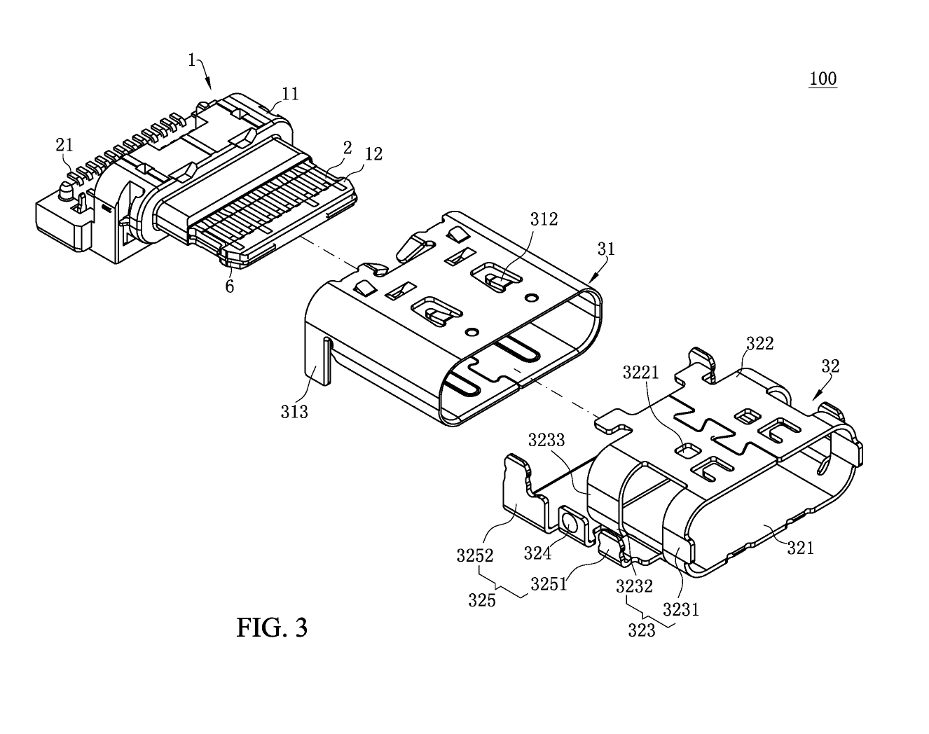

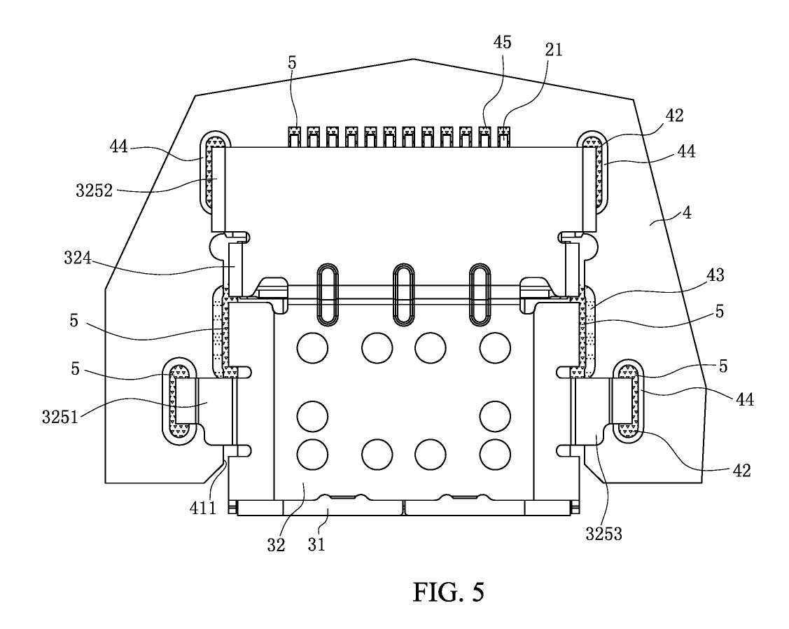

As shown in FIG. 2 and FIG. 3, the insulating body 1 has a base 11 and a tongue 12 extending forward from the base 11. The terminals 2 are retained on the base 11 in an upper row and a lower row and partially exposed from the upper surface and the lower surface of the tongue 12. Each terminal 2 has a soldering portion 21 extending out of the base 11 and electrically connected to each third contact area 45 (as shown in FIG. 5), and a middle shielding plate 6 is retained on the base 11 and the tongue 12 and located between the two rows of terminals 2.

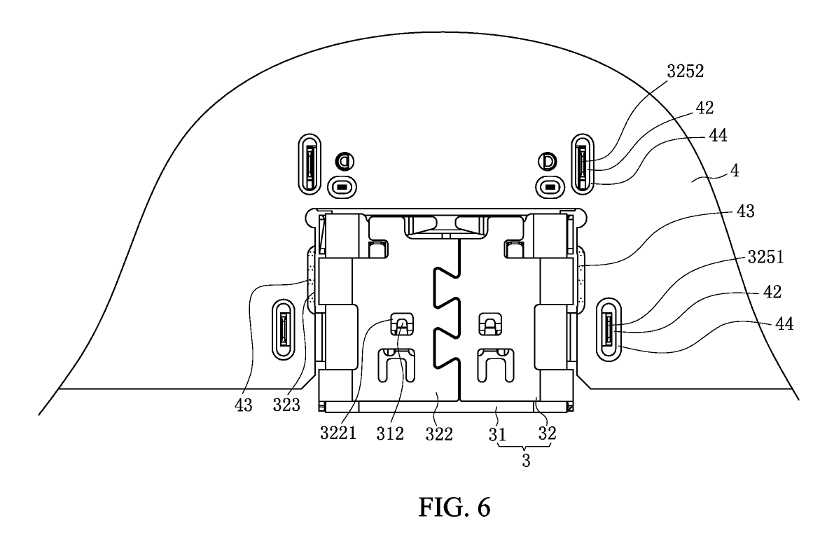

As shown in FIG. 2 and FIG. 3, the shielding shell 3 includes an inner shell 31 and an outer shell 32. The inner shell 31 is located in the sink plate groove 41, the inner shell 31 is surroundingly provided outside the tongue 12 to form an insertion space 311 for inserting a mating connector (not shown in the figures, similarly hereinafter). As shown in FIG. 3, at least one elastic sheet 312 extending to the insertion space 311 is provided on the bottom surface of the inner shell 31. The elastic sheet 312 abuts a shell of the butting connector, and a first abutting portion 313 extends upward from each of the two sides of the tail end of the inner shell 31. The outer shell 32 is sleeved on the inner shell 31 and has a top wall 321 and a bottom wall 322 opposite to the top wall 321. Each of the two sides of the top wall 321 respectively bends and extends towards the inner shell 31 to form a side wall 323. The side walls 323 are connected with the top wall 321 and the bottom wall 322. The top wall 321, the bottom wall 322 and the two side walls 323 jointly surround the inner shell 31. The bottom wall 322 is provided with a reserved hole 3221 (as shown in FIG. 3 and FIG. 6) corresponding to the elastic sheet 312. The side wall 323 includes a front wall 3231 and a rear wall 3232. The outer surface of the rear wall 3232 is a vertical abutting surface 3233, and the vertical abutting surface 3233 is in electrical contact with the first contact area 43 and the area of the vertical abutting surface 3233 is smaller than the area of the first contact area 43. In this embodiment, as shown in FIG. 5, the vertical abutting surface 3233 is fixed with the first contact area 43 by soldering via a solder paste 5. In other embodiments, the vertical abutting surface 3233 may be fixed in other manners, which are not limited herein.

As shown in FIG. 2 and FIG. 3, the outer shell 32 includes at least one mounting pin 325 mounted to the circuit board 4. The mounting pin 325 includes two first mounting portions 3251 and two second mounting portions 3252. The first mounting portions 3251 respectively extend from the two sides of the front end of the outer shell 32. Each first mounting portion 3251 has a first supporting portion 3253, and the first supporting portion 3253 abuts the circuit board 4. The second mounting portions 3252 respectively extend from the two sides of the tail end of the outer shell 32. The first mounting portions 3251 are respectively electrically connected with the second contact areas 44 on the left and right sides of the sink plate groove 41, and the second mounting portions 3252 are respectively electrically connected with the second contact areas 44 on the rear side of the sink plate groove 41. The first contact area 43 is located between the first mounting portions 3251 and the second mounting portions 3252. The vertical abutting surface 3233 is also located between the first mounting portions 3251 and the second mounting portions 3252 and is opposite to the first contact area 43. In this embodiment, as shown in FIG. 5, the first mounting portions 3251 and the second mounting portions 3252 are respectively fixed with the second contact areas 44 by soldering via the solder paste 5. In other embodiments, the first mounting portions 3251 and the second mounting portions 3252 may be fixed in other manners, which are not limited herein.

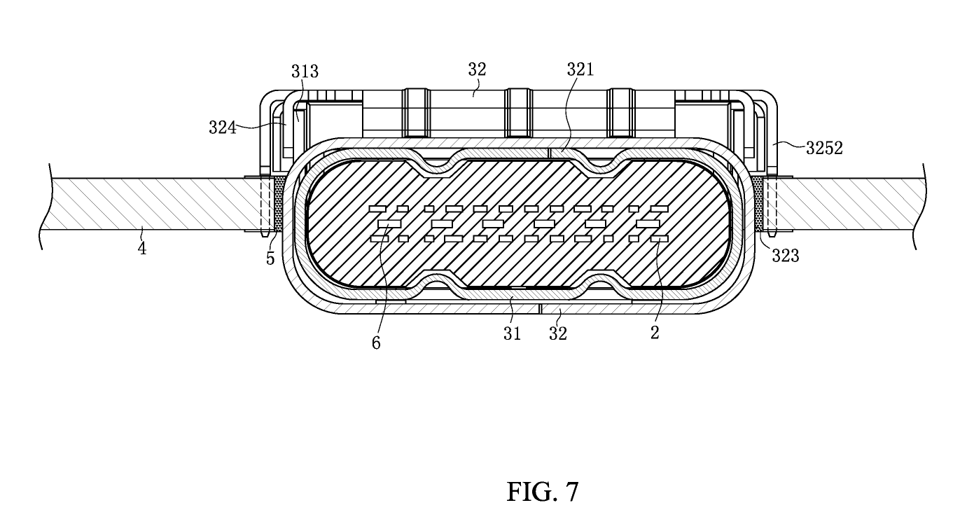

As shown in FIG. 1 and FIG. 7, a second abutting portion 324 respectively extends downward from each of the two sides of the tail end of the outer shell 32. The second abutting portions 324 are located between the first mounting portions 3251 and the second mounting portions 3252, and the second abutting portions 324 abut the first abutting portions 313 in a plate surface abutting manner. The first abutting portions 313 are further fixed with the second abutting portions 324 in a soldering manner, so as to improve the bonding strength of the inner shell 31 and the outer shell 32.

As shown in FIG. 4 and FIG. 6, during soldering, the first mounting portions 3251 and the second mounting portions 3252 are correspondingly mounted in the mounting holes 42 respectively to position the electrical connector 100. Then the soldering portions 21 are simultaneously soldered to the third contact areas 45. The side walls 323 are soldered to the first contact area 43, and the first mounting portions 3251 and the second mounting portions 3252 are respectively soldered to the second contact areas 44 (as shown in FIG. 5). Compared with the existing electrical connector 100 mounted to the circuit board 4 via the first mounting portions 3251 and the second mounting portions 3252 only, the electrical connector 100 according to certain embodiments of the present invention has the advantages that the side walls 323 are soldered to the first contact area 43, such that the electrical connector 100 is mounted to the circuit board 4 more stably and will not be separated from the circuit board 4 due to up-down shaking during insertion, and the service life of the electrical connector 100 is prolonged.

To sum up, the electrical connector 100 according to certain embodiments of the present invention has the following beneficial effects:

(1) The groove wall 411 of the circuit board 4 has the first contact area 43, and the outer shell 32 is electrically connected with the first contact area 43. Thus, compared with the existing electrical connector 100 which is fixed to the circuit board 4 via mounting pins 325 only, the electrical connector 100 according to certain embodiments of the present invention is fixed to the circuit board 4 more stably, will not be separated from the circuit board 4 due to multiple times of insertion shaking, and is ensured to work stably;

(2) The first contact area 43 is exposed to the sink plate groove 41 to facilitate soldering between the first contact area 43 and the vertical abutting surface 3233, and the first contact area 43 does not exceed the surface of the groove wall 411, so as to prevent the first contact area 43 from interfering with the outer shell 32 and ensure that the electrical connector 100 is soldered easily;

(3) The elastic sheet 312 extending to the insertion space 311 is provided on the bottom surface of the inner shell 31. The elastic sheet 312 is used for abutting the shell of the mating connector, holding the mating connector in the vertical direction and increasing a grounding path. The bottom wall 322 is provided with a reserved hole 3221 corresponding to the elastic sheet 312, and the reserved hole 3221 reserves the elastic sheet 312, such that the electrical connector 100 is inserted with the butting connector more stably and does not loosen up and down, and the grounding effect of the electrical connector 100 is strengthened at the same time;

(4) The side wall 323 includes the front wall 3231 and the rear wall 3232. The outer surface of the rear wall 3232 is the vertical abutting surface 3233. The vertical abutting surface 3233 is in electrical contact with the first contact area 43 and the area of the vertical abutting surface 3233 is smaller than the area of the first contact area 43, and the vertical abutting surface 3233 is thus ensured to be accurately soldered into the first contact area 43; and

(5) The first contact area 43 is located between the first mounting portions 3251 and the second mounting portions 3252. The vertical abutting surface 3233 is also located between the first mounting portions 3251 and the second mounting portions 3252 and is opposite to the first contact area 43, in which the first contact area 43 is staggered with the first mounting portions 3251 and the second mounting portions 3252, such that the electrical connector 100 does not affect the soldering of the first mounting portions 3251 and the second mounting portions 3252 when the first contact area 43 is soldered with the vertical abutting surface 3233, and the soldering procedure is operated better.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electrical connector, configured to be electrically connected to a circuit board, wherein the circuit board has a sink plate groove, the electrical connector is mounted in the sink plate groove, the sink plate groove has at least one groove wall, and the groove wall has at least one first contact area; the electrical connector comprising:
an insulating body;
a plurality of terminals, accommodated in the insulating body;
an inner shell, accommodated in the insulating body; and
an outer shell, provided outside the inner shell, and configured to be electrically connected with the at least one first contact area.

2. The electrical connector according to claim 1, wherein the outer shell has a top wall and two side walls connected with the top wall, and outer surfaces of the side walls are configured to be electrically connected with the at least one first contact area.

3. The electrical connector according to claim 2, wherein a bottom wall is opposite to the top wall, the side walls are connected with the top wall and the bottom wall, and the top wall, the side walls and the bottom wall are surroundingly provided outside the inner shell.

4. The electrical connector according to claim 2, wherein each of the side walls has a vertical abutting surface, and the vertical abutting surface is configured to be electrically connected with the first contact area.

5. The electrical connector according to claim 2, wherein an area of the first contact area is greater than an area of the vertical abutting surface.

6. The electrical connector according to claim 1, wherein the groove wall is concavely provided with a groove, the first contact area is located in the groove and exposed from the sink plate groove, and a surface of the first contact area does not exceed a surface of the groove wall.

7. The electrical connector according to claim 1, wherein the circuit board is provided with a plurality of second contact areas, the second contact areas are respectively located on a left side, a right side and a rear side of the sink plate groove, a plurality of mounting pins extend from two sides of the outer shell, at least one of the mounting pins extends from each of the two sides of the outer shell, and the mounting pins are configured to be electrically connected with the second contact areas.

8. The electrical connector according to claim 7, wherein each of the mounting pins comprises at least one first mounting portion and at least one second mounting portion, the first mounting portions of the mounting pins respectively extend from two sides of a front end of the outer shell, the second mounting portions of the mounting pins respectively extend from two sides of a tail end of the outer shell, the first mounting portions of the mounting pins are configured to be respectively electrically connected with the second contact areas on the left and right sides of the sink plate groove, the second mounting portions of the mounting pins are configured to be respectively electrically connected with the second contact areas on the rear side of the sink plate groove, and the first contact area is located between the first mounting portions and the second mounting portions of the mounting pins.

9. The electrical connector according to claim 1, wherein the insulating body is provided with a base and a tongue extending forward from the base, the terminals are retained on the base in an upper row and a lower row and are partially exposed from an upper surface and a lower surface of the tongue, a middle shielding plate is accommodated in the base and the tongue and located between the upper and lower rows of terminals, and the inner shell is surroundingly provided outside the tongue to form an insertion space therebetween.

10. The electrical connector according to claim 9, wherein the inner shell has at least one elastic sheet extending to the insertion space, and the outer shell is provided with a reserved hole corresponding to the elastic sheet.

11. The electrical connector according to claim 1, wherein a first abutting portion extends upward from each of two sides of a tail end of the inner shell, a second abutting portion extends downward from each of the two sides of a tail end of the outer shell, and the first abutting portion abuts the second abutting portion.

12. The electrical connector according to claim 11, wherein the first abutting portion is in plate surface contact with the second abutting portion.

13. An electrical connector, configured to be electrically connected to a circuit board, wherein the circuit board has a sink plate groove, the electrical connector is mounted in the sink plate groove, the sink plate groove has at least one groove wall, the groove wall has at least one first contact area, and the circuit board has a plurality of second contact areas outside the sink plate groove; the electrical connector comprising:
an insulating body;
a plurality of terminals, respectively accommodated in the insulating body; and
a shielding shell, accommodated in the insulating body and configured to be electrically connected with the first contact area, wherein at least two mounting pins respectively extend from two sides of the shielding shell and configured to be electrically connected with the second contact areas.

14. The electrical connector according to claim 13, wherein the shielding shell comprises an inner shell and an outer shell, the inner shell is accommodated in the insulating body, and the outer shell is provided outside the inner shell and configured to be electrically connected with the first contact area.

15. The electrical connector according to claim 14, wherein the outer shell has a top wall, a bottom wall opposite to the top wall and two side walls connected with the top wall and the bottom wall, and outer surfaces of the side walls are configured to be electrically connected with the first contact area.

16. The electrical connector according to claim 14, wherein each of a left side and a right side of the sink plate groove has one of the second contact areas, a rear side of the sink plate groove has two of the second contact areas, the at least two mounting pins comprise two first mounting portions, the two first mounting portions respectively extend from two sides of a front end of the outer shell and are configured to be respectively electrically connected with the second contact areas on the left side and the right side of the sink plate groove, and each of the first mounting portions has a first supporting portion configured to abut the circuit board.

17. The electrical connector according to claim 16, wherein the at least two mounting pins further comprise two second mounting portions, the two second mounting portions respectively extend from two sides of a tail end of the outer shell and are configured to be respectively electrically connected with the second contact areas on the rear side of the sink plate groove, and the first contact area is located between the first mounting portions and the second mounting portions.

18. The electrical connector according to claim 17, wherein the circuit board has a plurality of mounting holes, the second contact areas are provided on the mounting holes, and the first mounting portions and the second mounting portions are mounted in the mounting holes and configured to be fixed with the mounting holes by soldering.

19. The electrical connector according to claim 17, wherein a first abutting portion extends upward from each of two sides of the inner shell, a second abutting portion extends downward from each of the two sides of the outer shell, the second abutting portion is located between the first mounting portions and the second mounting portions, a first abutting portion extends upward from each of two sides of the inner shell, and the first abutting portion abuts the second abutting portion.

20. The electrical connector according to claim 17, wherein the side walls comprise a front wall and a rear wall, the rear wall is configured to be electrically connected with the first contact area and is located between the first mounting portions and the second mounting portions, the rear wall has a vertical abutting surface, and an area of the first contact area is greater than an area of the vertical abutting surface.
